(19) United States
(12) Patent Application Publication
(10) Pub. No.: US 2015/0213841 A1
(43) Pub. Date: Jul. 30, 2015

(54) MEMORY CHIP AND MEMORY STORAGE DEVICE

(71) Applicant: EOREX CORPORATION, HSINCHU COUNTY (TW)

(72) Inventors: CHENG-LUNG LIN, HSINCHU COUNTY (TW); WAN-TUNG LIANG, HSINCHU COUNTY (TW); CHENG-WEI HSU, HSINCHU COUNTY (TW)

(73) Assignee: EOREX CORPORATION, HSINCHU COUNTY (TW)

(21) Appl. No.: 14/264,769

(22) Filed: Apr. 29, 2014

(30) Foreign Application Priority Data
Jan. 29, 2014 (TW) 103103489

(51) Int. Cl. G11C 5/06

(52) U.S. Cl. CPC G11C 5/066

(57) ABSTRACT

A memory chip is disclosed. The memory comprises a substrate and a plurality of memory pads. The plurality of memory pads are disposed around the substrate so as to form a [symbol] pattern, and the plurality of memory pads are configured in a mirror horizontal manner and with layout line connectivity, so as to simplify complexity of layout line. Mirror solder ball map of the instant disclosure increases design flexibility and convenience of integrating line characteristics of the end product's application, and is easy to achieve the design of doubling the memory capacity.

### BACKGROUND OF THE INVENTION

1. Field of the Invention

The instant disclosure relates to a semiconductor memory storage device; in particular, to a memory having ball layout with mirror symmetry.

2. Description of Related Art

With the microelectronic technology rapidly developed, peripheral devices of various computer products become advanced, and nowadays consumers use computer products not only for general paper work and surfing the Internet but also for watching videos with high definitions, enjoying the 3D on-line games or dealing with complex application. However, no matter it is the videos with high definitions or kinds of electric documents that are discussed herein, it's known that the file size would be larger if the data becomes more complex. Therefore, the hard disk with high capacity becomes essential for all computer products.

In the prior art, the memory device is generally provided as the inner semiconductor integrated circuit in computers or other electric devices. The memory device comprises various types of memories such as volatile memory and non-volatile memory. The volatile memory can store the data even without power supply and comprises NAND flash, NOR flash, ROM, EEPROM, EPROM, PCRAM and other kinds of memories.

DRAM is one memory that has been most developed in the field of semiconductor and is widely used in server stations, laptops, personal computers, pads, host computers and play stations. Generally, the ball layout of DRAM is designed according to the standards set by the Joint Electron Device Engineering Council (JEDEC), but that ball layout is not in a mirror horizontal manner or a mirror vertical manner. Therefore, when it comes to certain applications which need larger memory capacity supports (that is, when there is a need to expand the memory capacity), the layout line could be rather complex, which may weaken signals or lower working frequency.

### SUMMARY OF THE INVENTION

The instant disclosure provides a memory. The memory comprises a substrate and a plurality of memory pads. The plurality of memory pads are disposed around the substrate so as to form a [symbol] pattern, and also the plurality of memory pads are configured in a mirror horizontal manner and with layout line connectivity so as to simplify complexity of layout line. The memory pads are divided into a first data region and a second data region, a first address region and a second address region, a first control region and a second control region, a first command region and a second command region, a first system voltage region and a second system voltage region, and a first ground region and a second ground region. The first data region and the second data region are configured to be electrically connected to a processing unit so as to be a data storage medium, and the first control region and the second control region are configured to be electrically connected to the processing unit so as to receive at least one control signal and to control the processing unit for accessing data of the first data region and the second data region.

In an embodiment of the instant disclosure, the plurality of memory pads in the first data region and the second data region are configured in a mirror horizontal manner, and the memory pads in the first address region and the second address region are configured in a mirror horizontal manner and with layout line connectivity.

In an embodiment of the instant disclosure, the memory pads in the first system voltage region and the second system voltage region are configured in a mirror horizontal manner, the memory pads in the first ground region and the second ground region are configured in a mirror horizontal manner, and the memory pads in the first command region and the second command region are configured in a mirror horizontal manner and with layout line connectivity.

In an embodiment of the instant disclosure, the memory pads in the first control region and the second control region are configured in a mirror horizontal manner and respectively disposed at a right side and a left side of the [symbol] pattern.

The instant disclosure provides a memory storage device. The memory storage device comprises a processing unit, a first memory and a second memory. The first memory is electrically connected to the processing unit and has a storage space of X bits wherein X is two to the power of N and N is an integer. The second memory is electrically connected to the first memory wherein the second memory and the first memory are the same. The first memory comprises a substrate and a plurality of memory pads. The plurality of memory pads are disposed around the substrate so as to form a [symbol] pattern, and the memory pads are configured in a mirror horizontal manner and with layout line connectivity. The plurality of memory pads are divided into a first data region and a second data region, a first address region and a second address region, a first control region and a second control region, a first system voltage region and a second system voltage region, and a first ground region and a second ground region. The first data region and the second data region are configured to be electrically connected to the processing unit so as to be a data storage medium. The first control region and the second control region are configured to be electrically connected to the processing unit so as to receive at least one control signal and to control the processing unit for accessing data of the first data region and the second data region. The first data regions of the first memory and the second memory are configured with layout line connectivity, the second data regions of the first memory and the second memory are configured with layout line connectivity, the first address regions of the first memory and the second memory are configured with layout line connectivity, the second address regions of the first memory and the second memory are configured with layout line connectivity, the first system voltage regions of the first memory and the second memory are configured with layout line connectivity, the second system voltage regions of the first memory and the second memory are configured with layout line connectivity, the first ground regions of the first memory and the second memory are configured with layout line connectivity, and the second ground regions of the first memory and the second memory are configured with layout line connectivity so as to expand memory capacity and to simplify complexity of layout line.

In an embodiment of the instant disclosure, the first memory and the second memory are configured in a mirror horizontal manner at one side of a circuit board.

In an embodiment of the instant disclosure, the first memory and the second memory are configured in a mirror vertical manner at two sides of a circuit board.

To sum up, in the memory and the memory storage device provided by the instant disclosure, via the mirror symmetry of the memory pads, the complexity of layout line could be dramatically simplified so as to prevent from weakening signals, lowering the working frequency, or etc. Such ball layout could increase the flexibility and the convenience regarding to designing layout having property integration, could have a signal docking directly to the mother board, and could also easily complete a design for expanding memory capacity.

For further understanding of the instant disclosure, reference is made to the following detailed description illustrating the embodiments and examples of the instant disclosure. The description is only for illustrating the instant disclosure, not for limiting the scope of the claim.

### BRIEF DESCRIPTION OF THE DRAWINGS

Embodiments are illustrated by way of example and not by way of limitation in the figures of the accompanying drawings, in which like references indicate similar elements and in which:

FIG. 1 shows a block diagram of a memory according to an embodiment of the instant disclosure;

FIG. 2 shows a block diagram of a memory storage device according to an embodiment of the instant disclosure;

FIG. 3 shows a schematic diagram of a memory storage device according to another embodiment of the instant disclosure; and

FIG. 4 shows a side view corresponding to the memory storage device shown according to the embodiment shown in FIG. 3.

### DETAILED DESCRIPTION OF PREFERRED EMBODIMENTS

The aforementioned illustrations and following detailed descriptions are exemplary for the purpose of further explaining the scope of the instant disclosure. Other objectives and advantages related to the instant disclosure will be illustrated in the subsequent descriptions and appended drawings. In the drawings, the size and relative sizes of layers and regions may be exaggerated for clarity.

It will be understood that, although the terms first, second, third, and the like, may be used herein to describe various elements, components, regions, layers and/or sections, these elements, components, regions, layers and/or sections should not be limited by these terms. These terms are only to distinguish one element, component, region, layer or section from another region, layer or section discussed below could be termed a second element, component, region, layer or section without departing from the teachings of the instant disclosure. As used herein, the term “and/or” includes any and all combinations of one or more of the associated listed items.

[One Embodiment of the Memory]

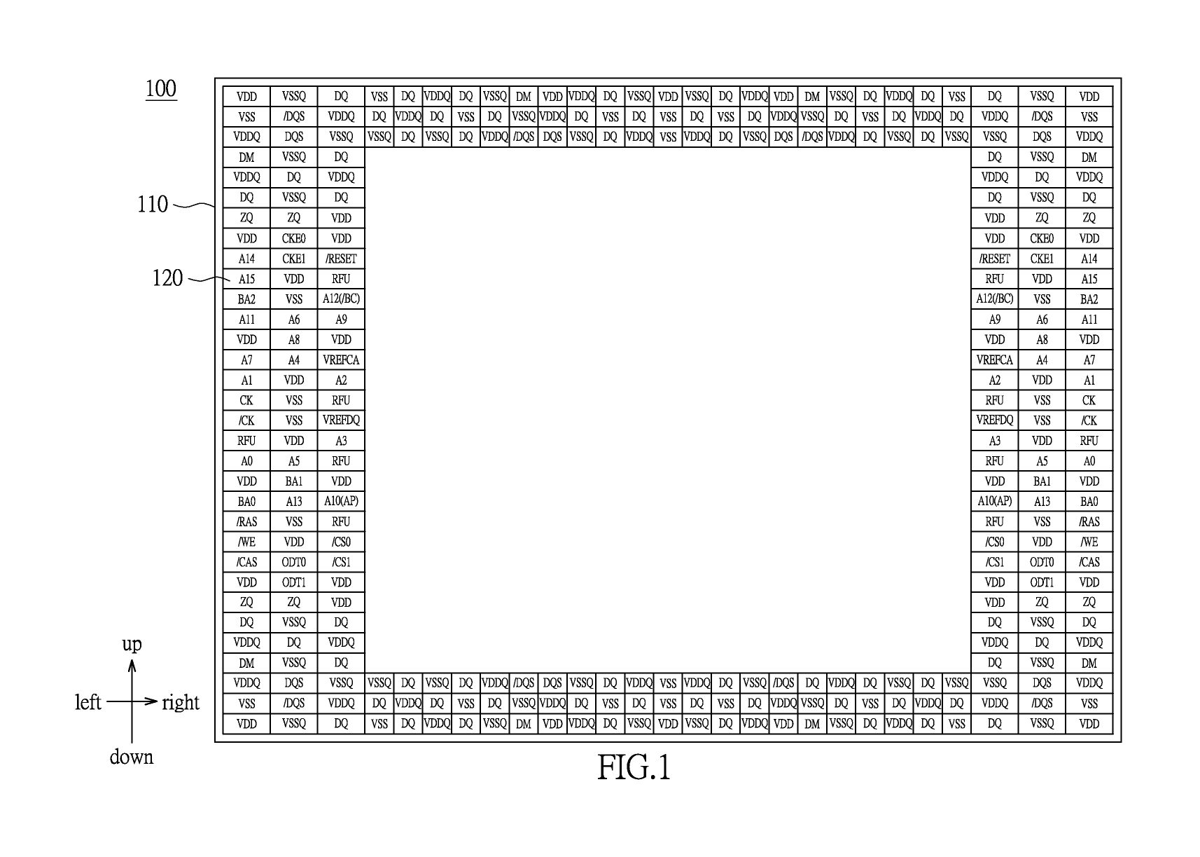

Please refer to FIG. 1, FIG. 1 shows a block diagram of a memory according to an embodiment of the instant disclosure. Generally, the ball layout of the Dynamic Random Access Memory (DRAM) is designed and regulated by the Joint Electron Device Engineering Council (JEDEC) and that ball layout is not in a mirror horizontal manner or a vertical manner. Therefore, when it comes to certain applications (such as smart phone, tablet or laptop) which need a larger memory capacity, the complexity of layout line would increase. Thus, a mirror solder ball map is chosen for the ball layout of the Integrated Circuit (IC) of the instant disclosure, which makes ball pads disposed around IC to form a [symbol] pattern wherein DQs are disposed at an upper side and a down side of the pattern. Moreover, some CTRL/CMD are disposed at a left side and a right side of the pattern, and the ball layout in the left-half area and the right-half area shows a complete mirror symmetry. Such ball layout could increase the flexibility and the convenience regarding to designing layout having property integration, could have a signal docking directly to the mother board, and could also easily complete a design for expanding memory capacity. The instant disclosure is different from the general ball layout of DRAM. The general ball layout of DRAM has no mirror symmetry, so when it needs to expand the memory capacity, the complexity increases in the line connections, which is also likely to weaken signals, lower working frequency or etc.

Before a further instruction, it should be clarified that, the ball layout of the memory 100 of the instant disclosure could be applied to the Double-Data-Rate Three Synchronous Dynamic Random Access Memory (DDR3 SDRAM) and the Double-Data-Rate Four (DDR4) lately released on Sep. 26, 2012, by the JEDEC that is responsible for the regulation regarding to the memory technology. It is worth mentioning that, the ball layout of the memory 100 of the instant disclosure could be further applied to all memory storage media. For further understanding of the instant disclosure, a memory with 64-bits storage capacity is taken for an example in the instant disclosure.

Please continually refer to FIG. 1, in the instant disclosure, the memory 100 comprises a substrate 110 and a plurality of memory pads 120. The plurality of memory pads 120 (such as DQ) are disposed around the substrate 110 so as to form a [symbol] pattern, and the plurality of memory pads are configured in a mirror horizontal manner and with layout line connectivity so as to simply the complexity of the layout line. The plurality of memory pads are divided into a first data region (such as the region where 32 DQs in the left-half area are disposed, DQ0˜DQ31) and a second data region (such as the region where 32 DQs in the right-half area are disposed), a first address region (such as the region where A0˜A15 in the left-half area are disposed) and a second address region (such as the region where A0˜A15 in the right-half area are disposed), a first control region (such as the region where /CS0, /CS1, /CKE0, /CKE1, ODT0 and ODT1 in the left-half area are disposed) and a second control region (such as the region where /CS0, /CS1, /CKE0, /CKE1, ODT0 and ODT1 in the right-half area are disposed), a first command region (such as the region where BA0, /RAS, /WE and /CAS in the left-half area are disposed) and a second command region (such as the region where BA0, /RAS, /WE and /CAS in the right-half area are disposed), a first system voltage region (such as the region where VDD and VDDQ in the left-half area are disposed) and a second system voltage region (such as the region where VDD and VDDQ in the right-half area are disposed), a first ground region (such as the region where VSS and VSSQ in the left-half area are disposed) and a second ground region (such as the region where VSS and VSSQ in the right-half area are disposed). The memory pads in the first control region and the second control region are configured in a mirror horizontal manner and respectively disposed at a left side and a right side of the [symbol] pattern, and the memory pads in the first command region and the second command region are respectively disposed at the left side and the right side of the [symbol] pattern. It is worth mentioning that, in order to have a configuration of the memory 100 in a mirror horizontal manner, there are a plurality of redundant memory pads disposed along a central line of the memory 100 (up to down, such as VDD, VSS, VSS, VSS, VSS and VDD), which is also for defining the left-half area and the right-half area. The first data region and the second data region are configured to be electrically connected to a processing unit (not shown in FIG. 1) so as to be a data storage medium, and the first control region and the second control region are configured to be electrically connected to the processing unit so as to receive at least one control signal and to control the processing unit for accessing data of the first data region and the second data region. The processing unit may be a central processing unit in a mobile device. Simply speaking, in the instant disclosure, in the memory 100, only A0˜A15, A0˜2, CK, /CK, CKE0˜1, /RAS, CAS, /WE, /CS0, /CS1, /RESET and ODT0˜1 (31 pads in total) are connected in the layout. The others are not connected in the layout although they are also configured to show mirror symmetry.

In details, the memory pads in the memory 100 of the instant disclosure are specially disposed to show a mirror symmetry. The memory pads in the first data region and the second data region are configured in a mirror horizontal manner. That is, memory pads DQ are configured in a mirror horizontal manner. The memory pads in the first address region and the second address region are configured in a mirror horizontal manner and with layout line connectivity. For example, the memory pads A0˜A15 are configured in a mirror horizontal manner, that is, the first address region (the left-half area) and the second address region (the right-half area) are symmetrical. The memory pads in the first system voltage region and the second system voltage region are configured in a mirror horizontal manner, and the memory pads in the first ground region and the second ground region are configured in a mirror horizontal manner. For example, the memory pads VDD and VDDQ in the left-half area are respectively symmetrical with the memory pads VDD and VDDQ in the right-half area, and the memory pads VSS and VSSQ in the left-half area are respectively symmetrical with the memory pads VSS and VSSQ in the right-half area. Moreover, the memory pads in the first command region and the second command region are configured in a mirror horizontal manner and with layout line connectivity, and the memory pads in the first command region and the second command region are respectively disposed at the left side and the right side of the [symbol] pattern. For example, the memory pads BA0, /RAS, /WE and /CAS in the left-half area are respectively symmetrical with the memory pads BA0, /RAS, /WE and /CAS in the right-half area. It is worth mentioning that, the memory pads in the first control region and the second control region are configured in a mirror horizontal manner and respectively disposed at the left-half area and the right-half area of the [symbol] pattern but without the layout line connectivity. Accordingly, via the ball layout of the memory pads in the memory 100, which is in a mirror horizontal manner, the layout line of the memory could be saved a lot.

For a specific instruction on an operation process of the memory 100 of the instant disclosure, there is at least one of the embodiments for further instruction.

In the following embodiments, there are only parts different from embodiments in FIG. 1 described, and the omitted parts are indicated to be identical to the embodiments in FIG. 1. In addition, for an easy instruction, similar reference numbers or symbols refer to elements alike.

[One Embodiment of the Memory Storage Device]

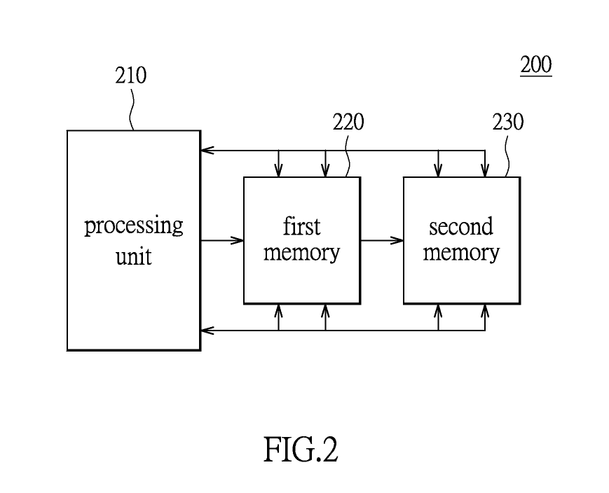

Please refer to FIG. 2, FIG. 2 shows a block diagram of a memory storage device according to an embodiment of the instant disclosure. The memory storage device 200 comprises a processing unit 210, a first memory 220 and a second memory 230. The first memory 220 is electrically connected to the processing unit 210, and the first memory 220 has a storage space of X bits wherein X is two to the power of N and N is an integer. In the instant disclosure, the first memory 220 and the second memory 230, for example, have a storage space of 64 bits, but it is not limited thereto. The first memory 220 is electrically connected to the processing unit 210 and the first memory 220, wherein the first memory 220 and the second memory 230 are substantially the same. Also, the memory pads inside the first memory 220 are disposed in the same manner with the memory 100 in the above mentioned embodiment shown in FIG. 1, and thus there's no need to go into details.

In the instant disclosure, the first memory 220 and the second memory 230 are disposed at one side of the circuit in a mirror horizontal manner. Furthermore, the memory pads in the first data region and the second data region of the first memory 220 and the second memory 230 are configured in a mirror horizontal manner and with layout line connectivity. Besides, the memory pads in the first address region and the second address region of the first memory 220 and the second memory 230 are configured in a mirror horizontal manner and with layout line connectivity, and the first address regions of the first memory 220 and the second memory 230 are configured with layout line connectivity. The memory pads in the first system voltage region and the second system voltage region of the first memory 220 and the second memory 230 are configured in a mirror horizontal manner and with layout line connectivity. In other words, the first system voltage region of the first memory 220 and the first system voltage region of the second memory 230 are configured with layout line connectivity. The memory pads in the first ground region and the second ground region of the first memory 220 and the second memory 230 are configured in a mirror horizontal manner and with layout line connectivity. In other words, the first ground region of the first memory 220 and the first ground region of the second memory 230 are configured with layout line connectivity. The memory pads in the first command region and the second command region of the first memory 220 and the second memory 230 are configured in a mirror horizontal manner and with layout line connectivity. In other words, signals transmitted to the memory pads 120 like A0˜A15, CK, /CK, CKE0˜1, /RAS, /WE, /CS0, /CS1, /RESET and ODT0˜ODT1 are transmitted by the processing unit to the left-half area of the first memory 320, and then the signals are transmitted from the left-half area of the first memory 320 to the right-half area of the first memory 320, then from the right-half area of the first memory 320 to the left-half area of the second memory 330, and finally from the left-half area of the second memory 330 to the right-half area of the second memory 330. Particularly, there are shared regions of other ball pads in the layout so as to reduce the complexity of layout line or the layout area. It is worth mentioning that, the memory pads 120 in the central portion (up to down, such as VDD, VSS, VSS, VSS, VSS and VDD) are considered a central line to define a left-half area and a right-half area.

As shown in FIG. 2, the processing unit 210 transmits a control signal from the central line to the first control region and the second control region of the first memory 220 and the second memory 230, and the processing unit 210 accesses data in the first data region and the second data region of the first memory 220 and the second memory 230 via lines at sides. It is worth mentioning that, the processing unit 210 determines to access data in the first memory 220 or in the second memory 230 via using the control signal transmitted to the memory pads /CS0 or CS1. Accordingly, via the layout of the memory pads of the instant disclosure, the complexity of layout line could be dramatically reduced so as to weaken signals, lower working frequency or etc.

In the following embodiments, there are only parts different from embodiments in FIG. 2 described, and the omitted parts are indicated to be identical to the embodiments in FIG. 2. In addition, for an easy instruction, similar reference numbers or symbols refer to elements alike.

[Another Embodiment of the Memory Storage Device]

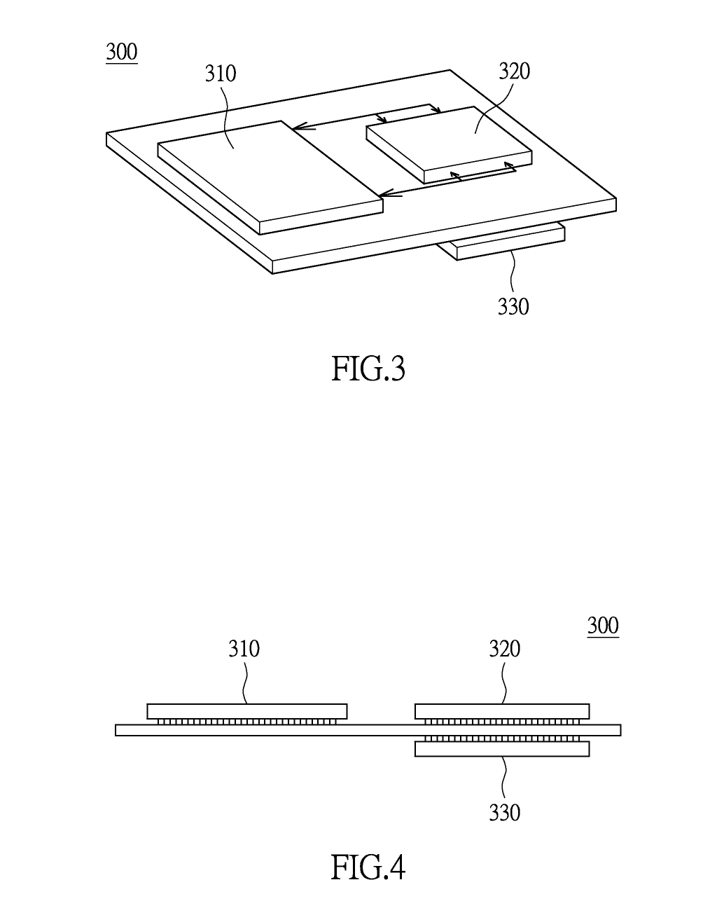

In conjunction with FIG. 3 and FIG. 4, FIG. 3 shows a schematic diagram of a memory storage device according to another embodiment of the instant disclosure and FIG. 4 shows a side view corresponding to the memory storage device shown according to the embodiment shown in FIG. 3. The memory storage device 300 comprises a processing unit 310, a first memory 320 and a second memory 330. Likewise, the first memory 320 is electrically connected to the processing unit 310, and the first memory 320 has a storage space of X bits wherein X is two to the power of N and N is an integer. The second memory 330 is electrically connected to the processing unit 310 and the first memory 320 wherein the second memory 330 and the first memory 320 are substantially the same. Also, the layout of memory pads in the first memory 320 is the same as the memory 100 in the embodiment shown in FIG. 1, and thus there is no need to go into details.

In the present embodiment, the first memory 320 and the second memory 330 are respectively disposed at two sides of the circuit board 340 and configured in a mirror vertical manner, as shown in FIG. 3. Furthermore, the memory pads in the first data region and the second data region of the first memory 320 and the second memory 330 are configured in a mirror horizontal manner and with layout line connectivity. Furthermore, the first data region of the first memory 320 and the second data region of the second memory 330 are disposed at two sides of the printed circuit board (PCB), corresponding with each other and share the lines of the PCB, and also the second data region of the first memory 320 and the first data region of the second memory 330 are disposed at two sides of the printed circuit board (PCB), corresponding with each other and sharing the lines of the PCB. Moreover, the memory pads in the first address region and the second address region of the first memory 320 and the second memory 330 are configured in a mirror horizontal manner and with layout line connectivity, and the first address regions of the first memory 320 and the second memory 330 are configured with layout line connectivity. The memory pads in the first system voltage region and the second system voltage region of the first memory 320 and the second memory 330 are configured in a mirror horizontal manner and with layout line connectivity. In other words, the first system voltage region of the first memory 320 and the first system voltage region of the second memory 330 are also configured with layout line connectivity. The memory pads in the first ground region and the second ground region of the first memory 320 and the second memory 330 are configured in a mirror horizontal manner and with layout line connectivity. That is, the first ground region of the first memory 320 and the first ground region of the second memory 330 are also configured with layout line connectivity. The memory pads in the first command region and the second command region of the first memory 320 and the second memory 330 are configured in a mirror horizontal manner and with layout line connectivity.

Similarly, in the present embodiment, the processing unit 310 transmits the control signal from the central line to the first control region and the second control region of the first memory 320 and the second memory 330, and the processing unit 310 accesses data in the first data region and the second data region of the first memory 320 and the second memory 330 via lines at sides. It is worth mentioning that, the processing unit 310 determines to access data in the first memory 320 or in the second memory 330 via using the control signal transmitted to the memory pads /CKE0 or /CKE1. Accordingly, via the layout of memory pads which is configured in a mirror horizontal manner, the instant disclosure can dramatically simplify the complexity of layout line so as to prevent from weakening signals or lowering working frequency. Moreover, the cost on the PCB with multiple layers could be reduced.

To sum up, in the memory and the memory storage device provided by the instant disclosure, via the mirror symmetry of the memory pads, the complexity of layout line could be dramatically simplified so as to prevent from weakening signals, lowering the working frequency, or etc. Such ball layout could increase the flexibility and the convenience regarding to designing layout having property integration, could have a signal docking directly to the mother board, and could also easily complete a design for expanding memory capacity.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A memory, comprising:
a substrate; and
a plurality of memory pads, disposed around the substrate so as to form a [symbol] pattern, configured in a mirror horizontal manner and with layout line connectivity, so as to simplify complexity of layout line, wherein the memory pads are divided into a first data region and a second data region, a first address region and a second address region, a first control region and a second control region, a first command region and a second command region, a first system voltage region and a second system voltage region, and a first ground region and a second ground region;
wherein the first data region and the second data region are configured to be electrically connected to a processing unit so as to be a data storage medium, and the first control region and the second control region are configured to be electrically connected to the processing unit so as to receive at least one control signal and to control the processing unit for accessing data of the first data region and the second data region.

2. The memory according to claim 1, wherein the plurality of memory pads in the first data region and the second data region are configured in a mirror horizontal manner, the memory pads in the first address region and the second address region are configured in a mirror horizontal manner and with layout line connectivity.

3. The memory according to claim 1, wherein the memory pads in the first system voltage region and the second system voltage region are configured in a mirror horizontal manner, the memory pads in the first ground region and the second ground region are configured in a mirror horizontal manner, and the memory pads in the first command region and the second command region are configured in a mirror horizontal manner and with layout line connectivity.

4. The memory according to claim 1, wherein the memory pads in the first control region and the second control region are configured in a mirror horizontal manner and respectively disposed at a right side and a left side of the [symbol] pattern.

5. A memory storage device, comprising:
a processing unit;
a first memory, electrically connected to the processing unit, having a storage space of X bits wherein X is two to the power of N and N is an integer; and
a second memory, electrically connected to the first memory, wherein the second memory and the first memory are the same, and the first memory comprising:
a substrate; and
a plurality of memory pads, disposed around the substrate so as to form a [symbol] pattern, and the memory pads are configured in a mirror horizontal manner and with layout line connectivity, wherein the plurality of memory pads are divided into a first data region and a second data region, a first address region and a second address region, a first control region and a second control region, a first system voltage region and a second system voltage region, and a first ground region and a second ground region;
wherein the first data region and the second data region are configured to be electrically connected to the processing unit so as to be a data storage medium, the first control region and the second control region are configured to be electrically connected to the processing unit so as to receive at least one control signal and to control the processing unit for accessing data of the first data region and the second data region wherein the first data regions of the first memory and the second memory are configured with layout line connectivity, the second data regions of the first memory and the second memory are configured with layout line connectivity, the first address regions of the first memory and the second memory are configured with layout line connectivity, the second address regions of the first memory and the second memory are configured with layout line connectivity, the first system voltage regions of the first memory and the second memory are configured with layout line connectivity, the second system voltage regions of the first memory and the second memory are configured with layout line connectivity, the first ground regions of the first memory and the second memory are configured with layout line connectivity, and the second ground regions of the first memory and the second memory are configured with layout line connectivity so as to expand memory capacity and to simplify complexity of layout line.

6. The memory storage device according to claim 5, wherein the first memory and the second memory are configured in a mirror horizontal manner at one side of a circuit board.

7. The memory storage device according to claim 5, wherein the first memory and the second memory are configured in a mirror vertical manner at two sides of a circuit board.

8. The memory storage device according to claim 5, wherein the memory pads in the first data region and the second data region are configured in a mirror horizontal manner, and the memory pads in the first address region and the second address region are configured in a mirror horizontal manner and with layout line connectivity.

9. The memory storage device according to claim 5, wherein the memory pads in the first system voltage region and the second system voltage region are configured in a mirror horizontal manner, the memory pads in the first ground region and the second ground region are configured in a mirror horizontal manner, and the memory pads in the first command region and the second command region are configured in a mirror horizontal manner and with layout line connectivity.

10. The memory storage device according to claim 5, wherein the memory pads in the first control region and the second control region are configured in a mirror horizontal manner and respectively disposed at a left side and a right side of the [symbol] pattern, and the memory pads in the first command region and the second command region are respectively disposed at the left side and the right side of the [symbol] pattern.
